(19) United States
(12) Patent Application Publication
(10) Pub. No.: US 2024/0030297 A1
(43) Pub. Date: Jan. 25, 2024

(54) INTEGRATED STRUCTURE OF SEMICONDUCTOR DEVICES HAVING SHARED CONTACT PLUG AND MANUFACTURING METHOD THEREOF

(71) Applicant: Richtek Technology Corporation, Zhubei City (TW)

(72) Inventors: Chin-Chin Tsai, Tainan (TW); Han-Chung Tai, Hsinchu (TW); Yong-Zhong Hu, Hsinchu (TW)

(21) Appl. No.: 18/314,684

(22) Filed: May 9, 2023

(30) Foreign Application Priority Data
Jul. 22, 2022 (TW) 111127659

(51) Int. Cl. H01L 29/417; H01L 29/423; H01L 29/40

(52) U.S. Cl. CPC H01L 29/41725; H01L 29/42376; H01L 29/401

(57) ABSTRACT

An integrated structure of semiconductor devices having a shared contact plug includes: a first device, a second device and a shared contact plug. The first device includes a first gate having a conduction region, two spacer regions and a protection region. The two spacer regions overlay and are connected with two ends of the conductive region, respectively. The protection region overlays and is connected with the spacer region located outside a shared side of the conductive region. The second device includes a shared region, wherein the shared region is located in a semiconductor layer which is located below and outside the protection region. The shared contact plug is formed on and in contact with the conductive region and the shared region. The first gate is electrically connected with the shared region through the shared contact plug, wherein the shared contact plug overlays and is connected with the protection region.

### CROSS REFERENCE

The present invention claims priority to TW 111127659 filed on Jul. 22, 2022.

### BACKGROUND OF THE INVENTION

### Field of Invention

The present invention relates to an integrated structure of semiconductor devices having a shared contact plug and a manufacturing method thereof; particularly, it relates to such integrated structure of semiconductor devices having a shared contact plug and such manufacturing method thereof capable of shortening distances among devices and preventing spacer and semiconductor layers from being damaged.

### Description of Related Art

Please refer to FIG. 1, which shows a top view of a prior art including two conventional adjacent semiconductor devices 11 and 12 connected with each other via an electrical connection structure 101. As shown in FIG. 1, the semiconductor device 11 includes a gate 1071, a source 108a and a drain 109a, wherein the gate 1071 includes a conduction layer 1071a and two spacer layers 1071b; besides, the semiconductor device 12 includes a gate 1072, a source 108b and a drain 109b, wherein the gate 1072 includes a conduction layer 1072a and two spacer layers 1072b. In circuit design, if it is required for the conduction layer 1071a of the gate 1071 of the semiconductor device 11 to be electrically connected to the source 108b of the adjacent semiconductor device 12 via the electrical connection structure 101 (which includes a contact plug 102a, a metal wire 101′ and a contact plug 102b), the electrical connection structure 101 needs to be formed by adopting at least two lithography process steps and at least two etching process steps. In this case, the distance d between the gate 1071 and the source 108b must be long enough to accommodate the formation of the electrical connection structure 101 (which includes the contact plug 102a, the metal wire 101′ and the contact plug 102b). Consequently, the prior art shown in FIG. 1 needs to occupy a large space and is difficult to shrink size.

In view of the above, the present invention proposes an integrated structure of semiconductor devices having a shared contact plug and a manufacturing method thereof, which can overcome the above-mentioned drawbacks in the prior art and avoid damaging the spacer regions and the semiconductor layer.

### SUMMARY OF THE INVENTION

From one perspective, the present invention provides an integrated structure of semiconductor devices having a shared contact plug, comprising: a first device including a first gate, wherein the first gate has a conduction region, two spacer regions and a protection region, wherein the two spacer regions overlay and are connected with two lateral sides of the conductive region, respectively, wherein one of the lateral sides is a shared side and wherein the protection region overlays and is connected with one of the spacer regions which is located at the shared side of the conductive region; a second device including a shared region, wherein the shared region is located in a semiconductor layer which is located below and outside the protection region; and a shared contact plug formed on and in contact with the conductive region and the shared region, wherein the first gate is electrically connected to the shared region via the shared contact plug; wherein the shared contact plug overlays and is connected with the protection region.

In one embodiment, the integrated structure of semiconductor devices having a shared contact plug further comprises a high voltage device, wherein the high voltage device includes a split gate, wherein the split gate has a field oxide region, wherein the protection region and the field oxide region are formed by one same deposition process step and one same patterning process step.

In one embodiment, the integrated structure of semiconductor devices having a shared contact plug further comprises: a high voltage device, wherein the high voltage device includes a silicide alignment block (SAB) oxide region, wherein the protection region and the SAB oxide region are formed by one same deposition process step and one same patterning process step.

In one embodiment, a length of the protection region is ½-fold to ⅓-fold of a length of the shared contact plug.

In one embodiment, the integrated structure of semiconductor devices having a shared contact plug further comprises: a contact etch stop layer (CESL), which is formed on the conduction region, the two spacer regions and the protection region, wherein the CESL serves to function as an etch stop layer in an etching process step for forming the shared contact plug.

In one embodiment, the first device and the second device are two metal oxide semiconductor (MOS) devices which are cross-coupling to each other in a static random access memory (SRAM).

From another perspective, the present invention provides a manufacturing method of an integrated structure of semiconductor devices having a shared contact plug, comprising steps of: forming a first gate of a first device, wherein the first gate has a conduction region, two spacer regions and a protection region, wherein the two spacer regions overlay and are connected with two lateral sides of the conductive region, respectively, wherein one of the lateral sides is a shared side and wherein the protection region overlays and is connected with one of the spacer regions which is located on the shared side of the conductive region; forming a shared region of a second device in a semiconductor layer which is located below and outside the protection region; and forming a shared contact plug on the conductive region and the shared region, wherein the first gate is electrically connected to the shared region via the shared contact plug; wherein the shared contact plug overlays and is connected with the protection region.

In one embodiment, the manufacturing method further comprises forming a high voltage device, wherein the step for forming the high voltage device includes: forming a split gate, wherein the split gate has a field oxide region.

In one embodiment, the manufacturing method further comprises: forming the protection region outside the spacer region on the shared side of the conductive region.

In one embodiment, the step for forming the protection region which is located outside the spacer region located outside the shared side which is one of the two sides of the conductive region includes: forming a field oxide layer on the first device, the second device and a second gate of the high voltage device; forming a top electrode layer on the field oxide layer; and removing a part of the field oxide layer and a part of the top electrode layer by a patterning process step, so as to form the protection region outside the spacer region on the shared side of the conductive region and at the same time to form the field oxide region.

In one embodiment, the manufacturing method further comprises: forming a high voltage device, wherein the step for forming the high voltage device includes: forming a silicide alignment block (SAB) oxide region.

In one embodiment, the step for forming the protection region outside the spacer region on the shared side of the conductive region includes: forming a SAB oxide region on the first device, the second device and a second gate of the high voltage device; forming a top electrode layer on the SAB oxide region; and removing a part of the SAB oxide region by a patterning process step, so as to form the protection region outside the spacer region on the shared side of the conductive region and at the same time to form the SAB oxide region.

In one embodiment, the manufacturing method further comprises: forming a field oxide layer on the first device, the second device, the second gate of the high voltage device and the SAB oxide region; forming a top electrode layer on the field oxide layer; and removing a part of the field oxide layer and a part of the top electrode layer by a patterning process step, so as to form a field oxide region of the high voltage device.

In one embodiment, subsequent to the step for forming the shared region of the second device, the manufacturing method further comprises: forming a contact etch stop layer (CESL) on the conduction region, the two spacer regions and the protection region, wherein the CESL serves to function as an etch stop layer in an etching process step for forming the shared contact plug.

In one embodiment, the step for forming the shared contact plug on the conduction region and the shared region includes: forming an interlayer dielectric layer on the first device, the second device and the high voltage device; removing a part of the interlayer dielectric layer and a part of the CESL, so as to form openings corresponding to a part of the conduction region, a part of shared region the and a part of the protection region; forming a contact plug layer via a deposition process step, wherein one of the openings is filled with the contact plug layer and the contact plug layer overlays the interlayer dielectric layer; and forming the shared contact plug in the opening by a chemical mechanical polishing process step.

Advantages of the present invention include: that the present invention can shorten the distance between devices via a shared contact plug; and that by adopting a protection region, the present invention can ensure the spacer regions and the semiconductor layer not to be etched in a lithography process step for forming the shared contact plug, so as to prevent the spacer regions and the semiconductor layer from being damaged.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a top view of a prior art structure wherein two adjacent semiconductor devices are connected via an electrical connection structure.

FIG. 2 shows a cross-section view of an integrated structure of semiconductor devices having a shared contact plug according to an embodiment of the present invention.

FIG. 3 shows a cross-section view of an integrated structure of semiconductor devices having a shared contact plug according to another embodiment of the present invention.

FIG. 4 shows a top view of an integrated structure of semiconductor devices having a shared contact plug according to another embodiment of the present invention.

FIG. 5A to FIG. 5H show cross-section views of a manufacturing method of an integrated structure of semiconductor devices having a shared contact plug according to an embodiment of the present invention.

FIG. 6A to FIG. 6H show cross-section views of a manufacturing method of an integrated structure of semiconductor devices having a shared contact plug according to another embodiment of the present invention.

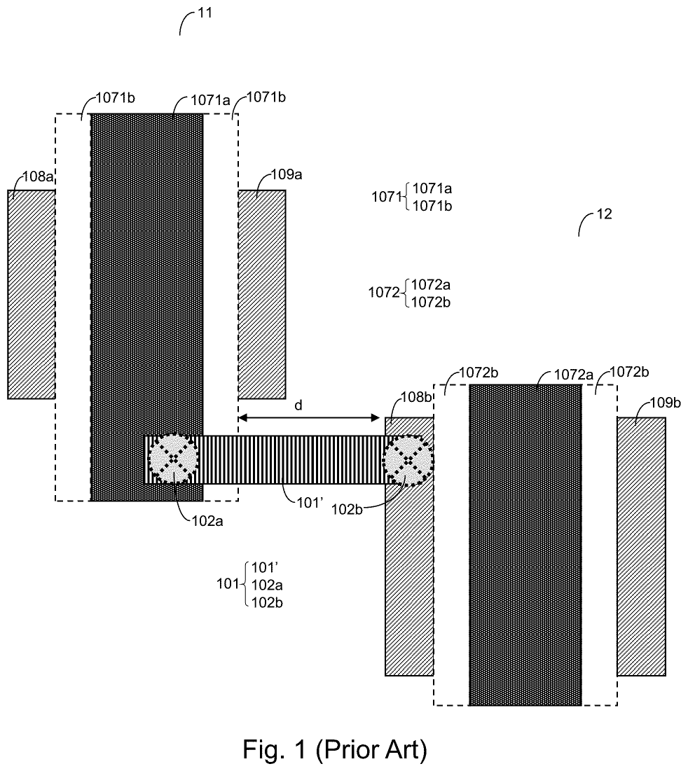

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

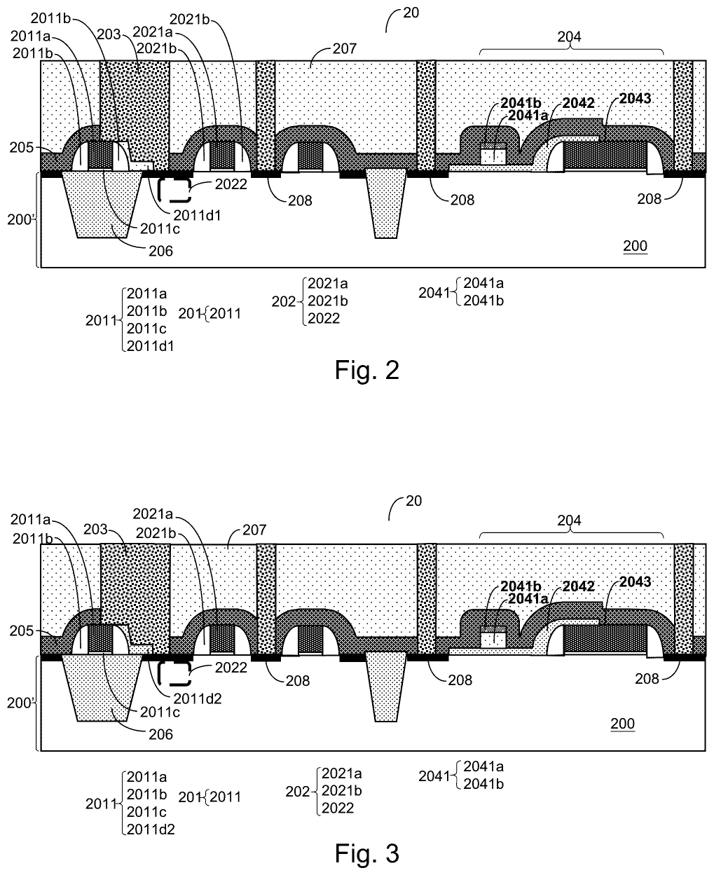

FIG. 2 shows a cross-section view of an integrated structure of semiconductor devices having a shared contact plug according to an embodiment of the present invention. As shown in FIG. 2, the integrated structure of semiconductor devices having a shared contact plug (integrated structure 20) of the present invention includes: a first device 201, a second device 202 and a shared contact plug 203. The first device 201 includes a first gate 2011. The first gate 2011 includes a conduction region 2011a, two spacer regions 2011b, a dielectric region 2011c and a protection region 2011d1. The two spacer regions 2011b overlay and are connected with two lateral sides of the conductive region 2011a, respectively. One of the two lateral sides of the conductive region 2011a is a shared side which is shared by two adjacent devices (i.e., the first and second devices have one common side providing functions for both devices). The protection region 2011d1 overlays and is connected with the spacer region 2011b located at the shared side of the conductive region 2011a. In one embodiment, the protection region 2011d1 is only formed at the shared side but not formed at the side opposite to the shared side. The conductive region 2011a is formed on the dielectric region 2011c. The dielectric region 2011c is formed on and in contact with a top surface 200a of the substrate 200. The conductive region 2011a for example includes an N-conductivity type polysilicon layer or a P-conductivity type polysilicon layer.

The second device 202 includes: a conduction region 2021a, two spacer regions 2021b and a shared region 2022, wherein the shared region 2022 is located in a semiconductor layer 200′ which is located below and outside the protection region 2011d1. In one embodiment, the shared region 2022 can be, for example but not limited to, a source, a drain or a drift region. The two spacer regions 2021b overlay and are connected with two lateral sides of the conductive region 2021a, respectively. An insulation structure 206 is formed below the first gate 2011.

The shared contact plug 203 is formed on and in contact with the conductive region 2011a and the shared region 2022, wherein the first gate 2011 is electrically connected to the shared region 2022 via the shared contact plug 203. An interlayer dielectric (ILD) layer 207 is formed on the first device 201, the second device 202 and the shared contact plug 203. The ILD layer 207 is for insulating metal layers in an integrated circuit (IC), which is well known to those skilled in the art, so the details thereof are not redundantly explained here. The shared contact plug 203 overlays and is connected with the protection region 2011d1.

As shown in FIG. 2, the integrated structure 20 further comprises: a high voltage device 204. The high voltage device includes: a split gate 2041, a silicide alignment block (SAB) oxide region 2042 and a second gate 2043. The split gate 2041 has a field oxide region 2041a and a top electrode 2041b. In this embodiment, the protection region 2011d1 and the field oxide region 2041a are formed by one same deposition process step and one same patterning process step. In one embodiment, a length of the protection region 2011d1 is ½-fold to ⅓-fold of a length of the shared contact plug 203. A contact etch stop layer (CESL) 205 is formed on the conduction regions 2011a and 2021a, the spacer regions 2011b and 2021b, the protection region 2011d1, the split gate 2041, the SAB oxide region 2042 and the second gate 2043, wherein the CESL 205 serves to function as an etch stop layer in an etching process step for forming the shared contact plug 203.

FIG. 3 shows a cross-section view of an integrated structure of semiconductor devices having a shared contact plug (integrated structure 20) according to another embodiment of the present invention. This embodiment of FIG. 3 is similar to the embodiment of FIG. 2, but is different in that: the protection region 2011d2 and the SAB oxide region 2042 are formed by one same deposition process step and one same patterning process step.

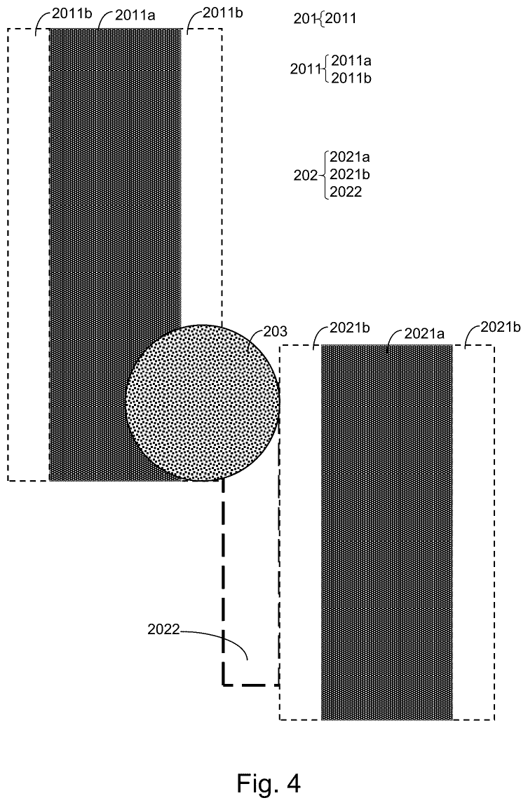

FIG. 4 shows a top view of an integrated structure of semiconductor devices having a shared contact plug according to an embodiment of the present invention. As shown in FIG. 4, the first device 201 and the second device 202 are, for example but not limited to, two metal oxide semiconductor (MOS) devices which are cross-coupling to each other via a shared contact plug 203 in a static random access memory (SRAM). To be more specific, referring to FIG. 4, the conductive region 2011a of the first gate 2011 of the first device 201 is coupled to the shared region 2022 of the second device 202 via the shared contact plug 203.

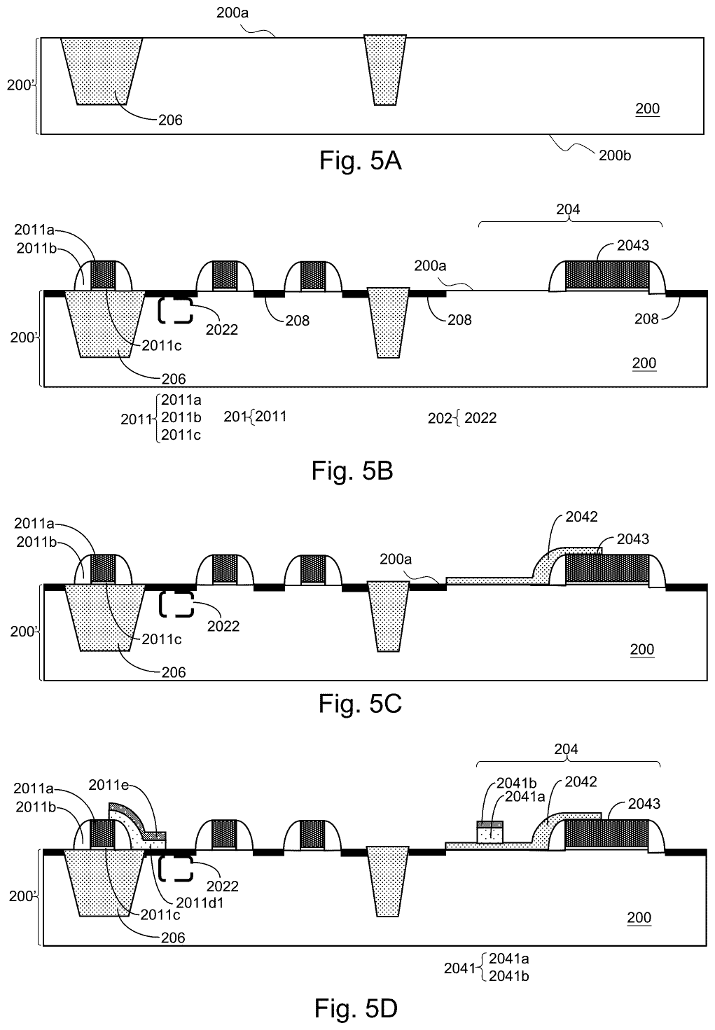

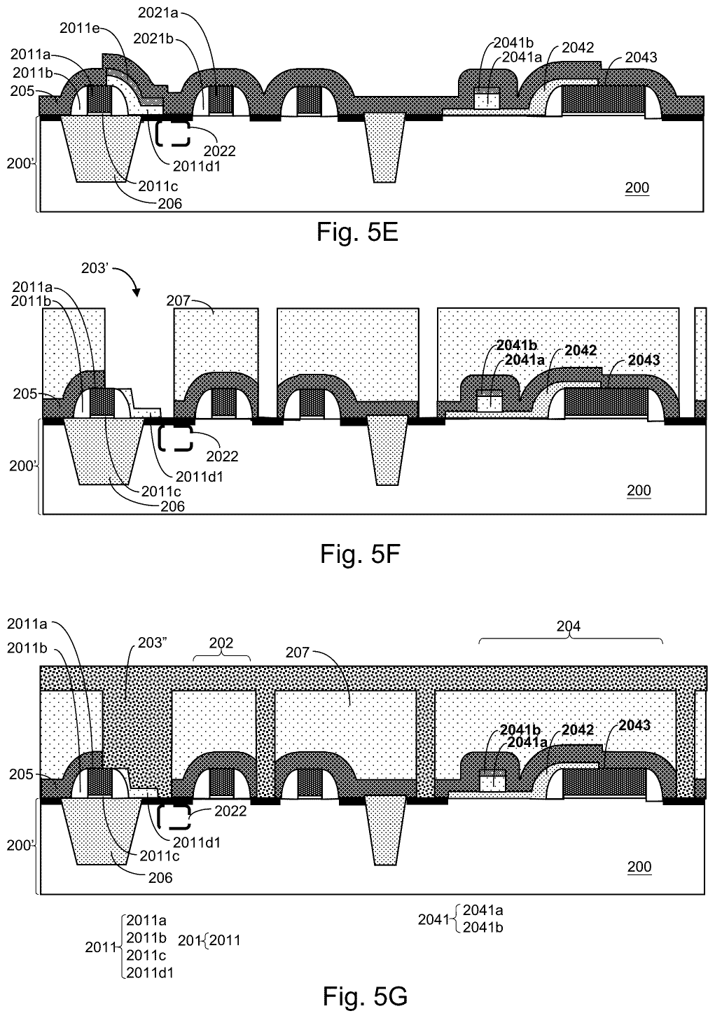

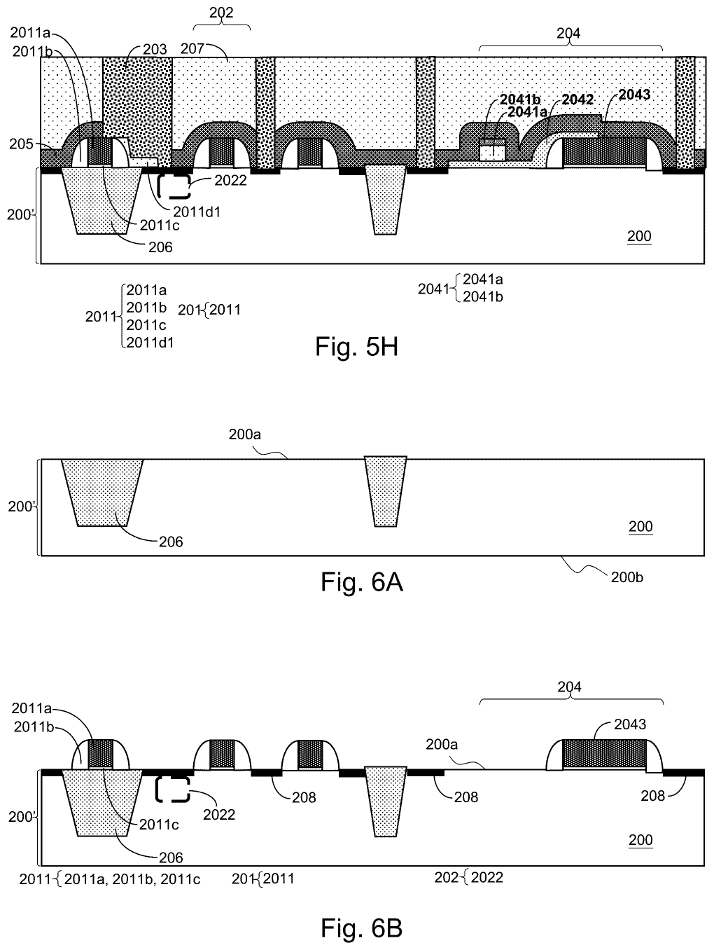

FIG. 5A to FIG. 5H show cross-section views of a manufacturing method of an integrated structure of semiconductor devices having a shared contact plug according to an embodiment of the present invention. As shown in FIG. 5A, first, a semiconductor layer 200′ is formed on a substrate 200. As shown in FIG. 5A, the semiconductor layer 200′ has a top surface 200a and a bottom surface 200b that is opposite to the top surface 200a in the vertical direction. An insulation structure 206 is formed below and in contact with the top surface 200a of the semiconductor layer 200′. The substrate 200 is, for example but not limited to, a P-conductivity type or an N-conductivity type silicon substrate. The semiconductor layer 200′, for example, is formed on the substrate 200 by an epitaxial growth process step, or a part of the substrate 200 is used as the semiconductor layer 200′. The semiconductor layer 200′ can be formed by any method known to a person having ordinary skill in the art, so the details thereof are not redundantly explained here.

Next, as shown in FIG. 5B, a first gate 2011 of a first device 201 and a second gate 2043 of a high voltage device 204 are formed on the top surface 200a. And, a shared region 2022 of the second device 202 is formed in the semiconductor layer 200′. And, a metal silicide region 208 is formed on the top surface 200a. In one embodiment, the shared region 2022 can be, for example but not limited to, a source, a drain or a drift region, wherein the source, the drain or the drift region can be formed by, for example but not limited to, an ion implantation process step which implants N-conductivity type impurities or P-conductivity type impurities in the form of accelerated ions into a defined region, to form the source, the drain or the drift region, which is well known to those skilled in the art, so the details thereof are not redundantly explained here.

Next, as shown in FIG. 5C, a silicide alignment block (SAB) oxide region 2042 is formed on the top surface 200a and on a part of the second gate 2043 by a patterning process step, wherein the patterning process step includes, for example but not limited to, a deposition process step and a lithography process step. Next, as shown in FIG. 5D, a split gate 2041 of the high voltage device 204 is formed on the SAB oxide region 2042 by a patterning process step, wherein the patterning process step includes, for example but not limited to, a deposition process step and a lithography process step. Besides, as shown in FIG. 5D, a protection region 2011d1 and a top electrode region 2011e are formed on a lateral side of the spacer region 2011b, which is the shared side of the conductive region 2011a of the first gate 2011, by a patterning process step, wherein the patterning process step includes, for example but not limited to, a deposition process step and a lithography process step. As shown in FIG. 5D, the top electrode region 2011e can serve as an etch stop layer.

In one embodiment, the step for forming the split gate 2041 of the high voltage device 204 on the SAB oxide region 2042 and the step for forming the protection region 2011d1 and the top electrode region 2011e on the shared side of the conductive region 2011a of the first gate 2011 include the following steps. First, a field oxide layer is formed on the first device 201, the second device 202, the shared region 2022 and the second gate 2043 of the high voltage device 204 by, for example but not limited to, a deposition process step. Next, a top electrode layer is formed on the field oxide layer by, for example but not limited to, a deposition process step. Next, a part of the field oxide layer and a part of the top electrode layer are removed by, for example but not limited to, a lithography process step, so as to form the protection region 2011d1 outside the spacer region 2011b and on the shared side of the conductive region 2011a of the first gate 2011, and at the same time to form the field oxide region 2041a and the top electrode 2041b. In one embodiment, the top electrode 2041b can be made of, for example but not limited to, polysilicon, titanium nitride (TiN), tantalum nitride or tungsten (W). In one embodiment, the field oxide region 2041a can be made of, for example but not limited to, tetraethoxysilane (TEOS). In one embodiment, the field oxide region 2041a can be formed by a high temperature oxidation (HTO) process step or a high aspect ratio process (HARP) process step.

Next, as shown in FIG. 5E, a contact etch stop layer (CESL) 205 is formed on the conduction regions 2011a and 2021a, the spacer regions 2011b and 2021b, the protection region 2011d1, the top electrode region 2011e, the split gate 2041, the SAB oxide region 2042 and a part of the second gate 2043, wherein the CESL 205 serves to function as an etch stop layer in an etching process step for forming the shared contact plug 203. In one embodiment, the CESL 205 can be made of, for example but not limited to, silicon nitride.

Next, in one embodiment, the step shown in FIG. 5F can be executed first, and the step shown in FIG. 5G can be executed subsequently. In one embodiment, as shown in FIG. 5F, an interlayer dielectric layer 207 is formed on the first device 201, the second device 202 and the CESL 205 of the high voltage device 204 by a patterning process step, wherein the patterning process step includes, for example but not limited to, a deposition process step and a lithography process step. Next, openings 203′ are formed at locations corresponding to a part of the conduction region 2011a, a part of shared region 2022 and a part of the protection region 2011d1. A contact plug layer 203″ is formed via a deposition process step, wherein the openings 203′ are filled with the contact plug layer 203″ and the contact plug layer 203″ overlays the interlayer dielectric layer 207. Next, as shown in FIG. 5H, the shared contact plug 203 is formed in one of the openings 203′ by a chemical mechanical polishing process step and the shared contact plug 203 is formed on the conductive region 2011a and the shared region 2022, wherein the first gate 2011 is electrically connected to the shared region 2022 via the shared contact plug 203, and wherein the shared contact plug 203 overlays and is connected with the protection region 2011d1.

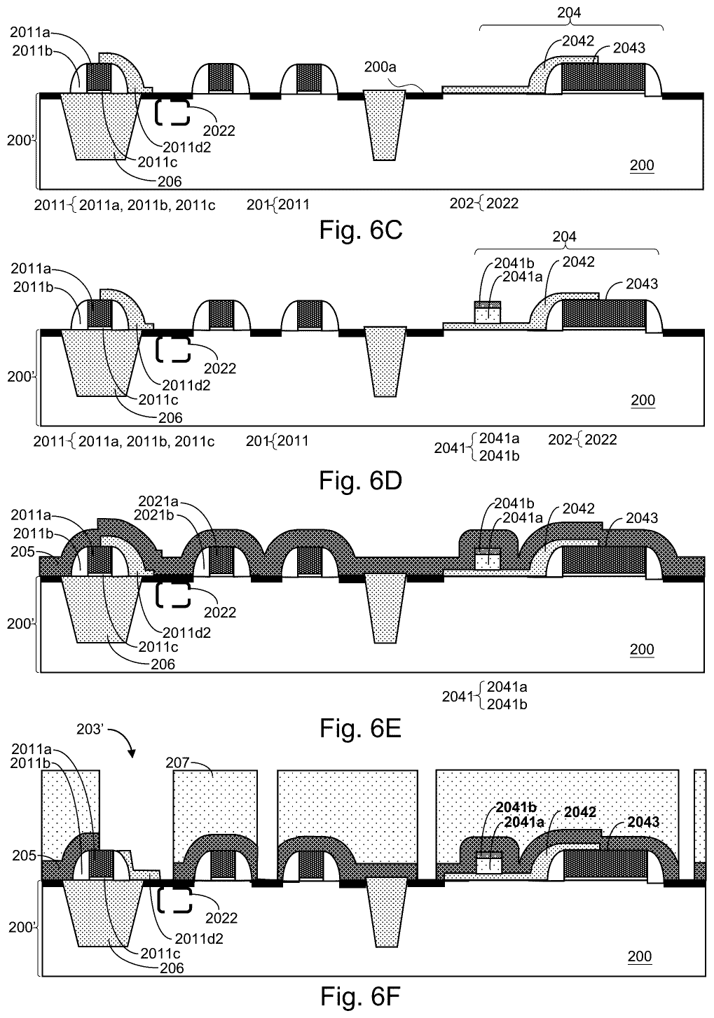

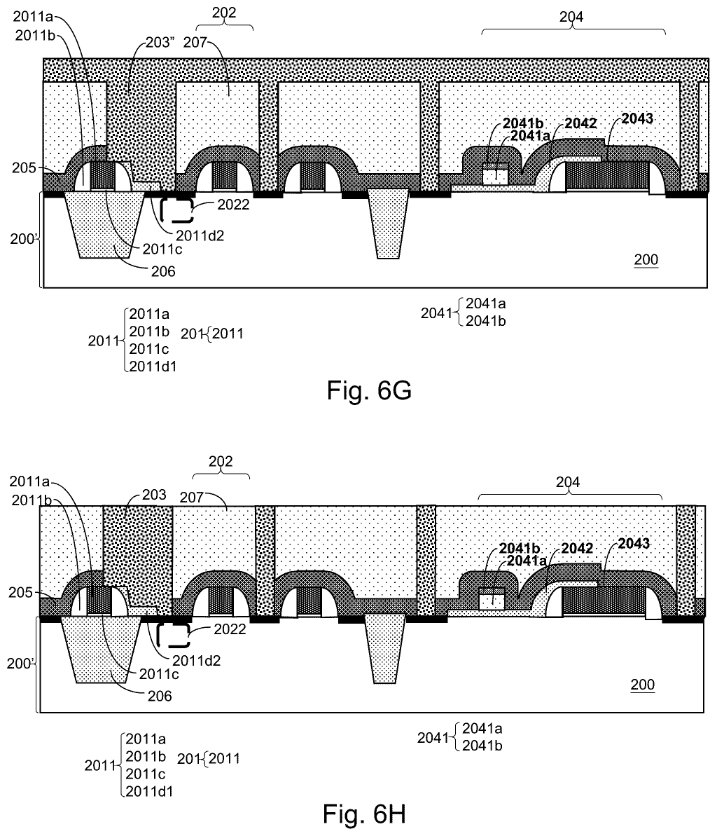

FIG. 6A to FIG. 6H show cross-section views of a manufacturing method of an integrated structure of semiconductor devices having a shared contact plug according to another embodiment of the present invention. As shown in FIG. 6A, first, a semiconductor layer 200′ is formed on a substrate 200. The semiconductor layer 200′ has a top surface 200a and a bottom surface 200b that is opposite to the top surface 200a in the vertical direction. An insulation structure 206 is formed below and in contact with a top surface 200a. As shown in FIG. 6A, The substrate 200 is, for example but not limited to, a P-conductivity type or an N-conductivity type silicon substrate. The semiconductor layer 200′, for example, is formed on the substrate 200 by an epitaxial growth process step, or a part of the substrate 200 is used as the semiconductor layer 200′. The semiconductor layer 200′ can be formed by any method known to a person having ordinary skill in the art, so the details thereof are not redundantly explained here.

Next, as shown in FIG. 6B, a first gate 2011 of a first device 201 and a second gate 2043 of a high voltage device 204 are formed on the top surface 200a. And, a shared region 2022 of the second device 202 is formed in the semiconductor layer 200′. And, a metal silicide region 208 is formed on the top surface 200a. Next, as shown in FIG. 6C, a protection region 2011d2 is formed outside the spacer region 2011b, on the shared side of the conductive region 2011a by a patterning process step, wherein the patterning process step includes, for example but not limited to, a deposition process step and a lithography process step. Besides, a silicide alignment block (SAB) oxide region 2042 is formed on the top surface 200a and on a part of the second gate 2043 by a patterning process step, wherein the patterning process step includes, for example but not limited to, a deposition process step and a lithography process step. In one embodiment, the step for forming the protection region 2011d2 on the shared side of the conductive region 2011a and the step for forming the SAB oxide region 2042 on the top surface 200a and on a part of the second gate 2043 include the following steps. First, a SAB oxide layer is formed on the first device 201, the second device 202, the shared region 2022 and the second gate 2043 of the high voltage device 204 by, for example but not limited to, a deposition process step. Next, a part of the SAB oxide layer is removed by, for example but not limited to, a lithography process step, so as to form the protection region 2011d2 outside the spacer region 2011b and on the shared side of the conductive region 2011a, and at the same time to form the SAB oxide region 2042. Next, as shown in FIG. 6D, a split gate 2041 of the high voltage device 204 is formed on the SAB oxide region 2042 by a patterning process step, wherein the patterning process step includes, for example but not limited to, a deposition process step and a lithography process step.

In one embodiment, the step for forming the split gate 2041 of the high voltage device 204 on the SAB oxide region 2042 include the following steps. First, a field oxide layer is formed on the first device 201, the second device 202, the shared region 2022 and the second gate 2043 of the high voltage device 204 by, for example but not limited to, a deposition process step. Next, a top electrode layer is formed on the field oxide layer by, for example but not limited to, a deposition process step. Next, a part of the field oxide layer and a part of the top electrode layer are removed by, for example but not limited to, a lithography process step, so as to form the field oxide region 2041a of the split gate 2041 and the top electrode 2041b.

Next, as shown in FIG. 6E, a contact etch stop layer (CESL) 205 is formed on the conduction regions 2011a and 2021a, the spacer regions 2011b and 2021b, the protection region 2011d2, the split gate 2041, the SAB oxide region 2042 and a part of the second gate 2043, wherein the CESL 205 serves to function as an etch stop layer in an etching process step for forming the shared contact plug 203. In one embodiment, the CESL 205 can be made of, for example but not limited to, silicon nitride.

Next, in one embodiment, the step shown in FIG. 6F can be executed first, and the step shown in FIG. 6G can be executed subsequently. As shown in FIG. 6F, an interlayer dielectric layer 207 is formed on the first device 201, the second device 202 and the CESL 205 of the high voltage device 204 by a patterning process step, wherein the patterning process step includes, for example but not limited to, a deposition process step and a lithography process step. Next, openings 203′ are formed at locations corresponding to a part of the conduction region 2011a, a part of shared region 2022 and a part of the protection region 2011d1. Next, as shown in FIG. 6G, a contact plug layer 203″ is formed via a deposition process step, wherein the openings 203′ are filled with the contact plug layer 203″ and the contact plug layer 203″ overlays the interlayer dielectric layer 207. Next, as shown in FIG. 6H, the shared contact plug 203 is formed in one of the openings 203′ by a chemical mechanical polishing process step and the shared contact plug 203 is on the conductive region 2011a and the shared region 2022, wherein the first gate 2011 is electrically connected to the shared region 2022 via the shared contact plug 203, and wherein the shared contact plug 203 overlays and is connected with the protection region 2011d2.

The present invention has been described in considerable detail with reference to certain preferred embodiments thereof. Advantages of the present invention include: that the present invention can shorten the distance between devices via a shared contact plug; and that by adopting a protection region, the present invention can ensure the spacer regions and the semiconductor layer not to be etched in a lithography process step for forming the shared contact plug, so as to prevent the spacer regions and the semiconductor layer from being damaged.

It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, other process steps or structures, such as a light doping drain (LDD) region may be added. For another example, the lithography process step is not limited to the mask technology but it can also include electron beam lithography. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. An integrated structure of semiconductor devices having a shared contact plug, comprising:
a first device including a first gate, wherein the first gate has a conduction region, two spacer regions and a protection region, wherein the two spacer regions overlay and are connected with two lateral sides of the conductive region, respectively, wherein one of the lateral sides is a shared side and wherein the protection region overlays and is connected with one of the spacer regions which is located at the shared side of the conductive region;
a second device including a shared region, wherein the shared region is located in a semiconductor layer which is located below and outside the protection region; and
a shared contact plug formed on and in contact with the conductive region and the shared region, wherein the first gate is electrically connected to the shared region via the shared contact plug;
wherein the shared contact plug overlays and is connected with the protection region.

2. The integrated structure of semiconductor devices having a shared contact plug as claimed in claim 1, further comprising:
a high voltage device, wherein the high voltage device includes a split gate, wherein the split gate has a field oxide region, wherein the protection region and the field oxide region are formed by one same deposition process step and one same patterning process step.

3. The integrated structure of semiconductor devices having a shared contact plug as claimed in claim 1, further comprising:
a high voltage device, wherein the high voltage device includes a silicide alignment block (SAB) oxide region, wherein the protection region and the SAB oxide region are formed by one same deposition process step and one same patterning process step.

4. The integrated structure of semiconductor devices having a shared contact plug as claimed in claim 1, wherein a length of the protection region is ½-fold to ⅓-fold of a length of the shared contact plug.

5. The integrated structure of semiconductor devices having a shared contact plug as claimed in claim 1, further comprising:
a contact etch stop layer (CESL), which is formed on the conduction region, the two spacer regions and the protection region, wherein the CESL serves to function as an etch stop layer in an etching process step for forming the shared contact plug.

6. The integrated structure of semiconductor devices having a shared contact plug as claimed in claim 1, wherein the first device and the second device are two metal oxide semiconductor (MOS) devices which are cross-coupling to each other in a static random access memory (SRAM).

7. A manufacturing method of an integrated structure of semiconductor devices having a shared contact plug, comprising:
forming a first gate of a first device, wherein the first gate has a conduction region, two spacer regions and a protection region, wherein the two spacer regions overlay and are connected with two lateral sides of the conductive region, respectively, wherein one of the lateral sides is a shared side and wherein the protection region overlays and is connected with one of the spacer regions which is located on the shared side of the conductive region;
forming a shared region of a second device in a semiconductor layer which is located below and outside the protection region; and
forming a shared contact plug on the conductive region and the shared region, wherein the first gate is electrically connected to the shared region via the shared contact plug;
wherein the shared contact plug overlays and is connected with the protection region.

8. The manufacturing method as claimed in claim 7, further comprising forming a high voltage device, wherein the step for forming the high voltage device includes: forming a split gate, wherein the split gate has a field oxide region.

9. The manufacturing method as claimed in claim 8, further comprising:
forming the protection region outside the spacer region on the shared side of the conductive region.

10. The manufacturing method as claimed in claim 9, wherein the step for forming the protection region outside the spacer region on the shared side of the conductive region includes:
forming a field oxide layer on the first device, the second device and a second gate of the high voltage device;
forming a top electrode layer on the field oxide layer; and
removing a part of the field oxide layer and a part of the top electrode layer by a patterning process step, so as to form the protection region outside the spacer region on the shared side of the conductive region and at the same time to form the field oxide region.

11. The manufacturing method as claimed in claim 7, further comprising:
forming a high voltage device, wherein the step for forming the high voltage device includes: forming a silicide alignment block (SAB) oxide region.

12. The manufacturing method as claimed in claim 11, further comprising:
forming the protection region outside the spacer region on the shared side of the conductive region.

13. The manufacturing method as claimed in claim 12, wherein the step for forming the protection region outside the spacer region on the shared side of the conductive region includes:
forming a SAB oxide region on the first device, the second device and a second gate of the high voltage device;
forming a top electrode layer on the SAB oxide region; and
removing a part of the SAB oxide region by a patterning process step, so as to form the protection region outside the spacer region on the shared side of the conductive region and at the same time to form the SAB oxide region.

14. The manufacturing method as claimed in claim 13, further comprising following steps:
forming a field oxide layer on the first device, the second device, the second gate of the high voltage device and the SAB oxide region;
forming a top electrode layer on the field oxide layer; and
removing a part of the field oxide layer and a part of the top electrode layer by a patterning process step, so as to form a field oxide region of the high voltage device.

15. The manufacturing method as claimed in claim 7, wherein a length of the protection region is ½-fold to ⅓-fold of a length of the shared contact plug.

16. The manufacturing method as claimed in claim 7, further comprising following steps:
subsequent to the step for forming the shared region of the second device, forming a contact etch stop layer (CESL) on the conduction region, the two spacer regions and the protection region, wherein the CESL serves to function as an etch stop layer in an etching process step for forming the shared contact plug.

17. The manufacturing method as claimed in claim 16, wherein the step for forming the shared contact plug on the conduction region and the shared region includes following steps:
forming an interlayer dielectric layer on the first device, the second device and the high voltage device;
removing a part of the interlayer dielectric layer and a part of the CESL, so as to form openings corresponding to a part of the conduction region, a part of shared region and a part of the protection region;
forming a contact plug layer via a deposition process step, wherein one of the openings is filled with the contact plug layer and the contact plug layer overlays the interlayer dielectric layer; and
forming the shared contact plug in the opening by a chemical mechanical polishing process step.

18. The manufacturing method as claimed in claim 7, wherein the first device and the second device are two metal oxide semiconductor (MOS) devices which are cross-coupling to each other in a static random access memory (SRAM).
